(19) United States
(12) Patent Application Publication
(10) Pub. No.: US 2012/0155573 A1
(43) Pub. Date: Jun. 21, 2012

(54) Phase Shifting Circuitry

(75) Inventor: SÉBASTIEN PRUVOST, FROGES (FR)

(73) Assignee: STMICROELECTRONICS SA, MONTROUGE (FR)

(21) Appl. No.: 13/292,819

(22) Filed: Nov. 9, 2011

(30) Foreign Application Priority Data
Dec. 15, 2010 (FR) 10/60569

(51) Int. Cl. H04L 27/14; H03H 11/16; H04L 27/12

(52) U.S. Cl. 375/302; 375/322; 327/254

(57) ABSTRACT

Phase shifting circuitry is provided for phase shifting at least one of first and second quadrature components of a data signal. The circuitry includes a first phase shifter adapted to phase shift, by a first phase angle, the first quadrature component by adding together weighted versions of the first and second quadrature components.

### CROSS-REFERENCE TO RELATED APPLICATIONS

This application is a translation of and claims the priority benefit of French patent application number 10/60569, filed on Dec. 15, 2010, which is hereby incorporated by reference to the maximum extent allowable by law.

### TECHNICAL FIELD

The present invention relates in general to the field of RF transmitters and receivers, and more particularly to phase shifters and methods of phase shifting quadrature components of RF signals.

### BACKGROUND

Amplitude shift keying (ASK) and phase-shift keying (PSK) modulation schemes are based on the transmission and reception of quadrature components, generally labelled I and Q, which are waveforms that are out of phase by 90 degrees and represent data based on their phase. Examples of such schemes include 4-QAM (quadrature amplitude modulation), 8-QAM etc., QPSK (quadrature PSK), 8-PSK, differential PSK and Offset PSK. The transmission of such quadrature components generally involves modulating them by mixing them with an in quadrature carrier frequency signal.

In certain applications, such as in beam-forming applications, an antenna array is provided on the transmitter side for transmitting phase-shifted versions of the modulated signal. In particular, phase shifters are provided for phase-shifting the modulated signal by different amounts for transmission by corresponding antenna.

On the receive side, a plurality of receive antennas is provided, a corresponding phase shift being applied to the signal received from each antenna. Then, after demodulation by mixing with the in quadrature carrier frequency signal, the original quadrature components may be retrieved.

There are difficulties in implementing such QSK or PSK transmission and reception circuits. In particular, while it would be desirable to provide a system supporting high bandwidths, a difficulty occurs with accurately controlling the amplitudes of the transmitted signals, which can easily be distorted by the phase shifters at high frequencies of the modulation signal. Furthermore, it is difficult to precisely control the phase variation or group delay variation across the frequency bandwidth, particularly at high frequencies.

### SUMMARY OF THE INVENTION

Embodiments of the present invention at least partially address one or more difficulties in the prior art.

According to one aspect of the present invention, phase shifting circuitry is provided for phase shifting at least one of first and second quadrature components of a data signal. The circuitry comprises a first phase shifter adapted to phase shift, by a first phase angle, the first quadrature component by adding together weighted versions of the first and second quadrature components.

According to one embodiment, the phase shifting circuitry further comprises a second phase shifter adapted to phase shift, by the first phase angle, the second quadrature component by adding together weighted versions of the first and second quadrature components.

According to another embodiment, the first and second phase shifters each comprise at least one transistor for converting each of the first and second quadrature components into a current signal, and at least one resistor for adjusting each current signal to apply the weighting.

According to another embodiment, the first phase shifter is adapted to apply a weighting of cosφ to the first quadrature component and a weighting −sinφ to the second quadrature component, and the second phase shifter is adapted to apply a weighting of sinφ to the first quadrature component and a weighting cosφ to the second quadrature component, where φ is the first phase angle.

According to another embodiment, each of the first and second quadrature components is a differential signal comprising first and second differential components. The phase shifted first and second quadrature components each comprise first and second differential components generated based on the following formulas: Iₒᵤₜ₊=Iᵢₙ₊.cosφ+Qᵢₙ₋.sinφ; Iₒᵤₜ₋=Iᵢₙ₋.cosφ+Qᵢₙ₊.sinφ; Qₒᵤₜ₊=Qᵢₙ₊.cosφ+Iᵢₙ₊.sinφ; and Qₒᵤₜ₋=Qᵢₙ₋.cosφ+Iᵢₙ₋.sinφ.

According to another embodiment, the phase shifting circuitry further comprises a third phase shifter adapted to phase shift, by a second phase angle, the first quadrature component by adding together weighted versions of the first and second quadrature components, and a fourth phase shifter adapted to phase shift, by the second phase angle, the second quadrature component by adding together weighted versions of the first and second quadrature components.

According to another embodiment, each of the first and second quadrature components is a differential signal comprising first and second differential components. The first and second phase shifters each comprise first, second, third and fourth current branches each respectively comprising first, second, third and fourth transistors each coupled between an intermediate node and a corresponding current source. The first and second transistors are respectively controlled by the first and second differential components of the first quadrature component and the third and fourth transistors are respectively controlled by the first and second differential components of the second quadrature component. A first resistor is coupled between the first and second branches and a second resistor is coupled between the third and fourth branches. The resistance values of the first and second resistors determine the weighting values applied to first and second quadrature components respectively.

According to another embodiment, the first and second resistors are variable resistors controllable by a control signal.

According to another embodiment, the first and second resistors of the first phase shifter have resistances of Rcosφ and Rsinφ respectively, and the first and second resistors of the second phase shifter have resistances of Rsinφ and Rcosφ respectively, where R is a constant.

According to another embodiment, the first and second quadrature components represent data modulated based on phase shift keying or amplitude shift keying.

According to another embodiment, the first and second quadrature components represent data modulated based on quadrature phase shift keying.

According to another aspect of the present invention, RF transmission circuitry comprises the above phase shifting circuitry. A first mixer is adapted to multiply the phase shifted first quadrature component by a first carrier frequency signal. A second mixer is adapted to multiply the phase shifted second quadrature component by a second carrier frequency signal. The output of the first and second mixers are summed to provide a first phase shifted signal. An antenna is adapted to transmit the first phase shifted signal.

According to one embodiment, the RF transmission circuitry comprises the above first and second phase shifters, wherein the first mixer is coupled between a supply voltage and the first, second, third and fourth current branches of the first phase shifter. The second mixer is coupled between the supply voltage and the first, second, third and fourth current branches of the second phase shifter.

According to another aspect of the present invention, RF reception circuitry comprises the above phase shifting circuitry. An antenna is adapted to receive a first input signal. A first mixer adapted to multiply the first input signal by a first carrier frequency signal to generate the first quadrature component. A second mixer adapted to multiply the second input signal by a second carrier frequency signal to generate the second quadrature component.

Another aspect of the present invention provides a method of phase shifting at least one of first and second quadrature components of a data signal. The method comprises phase shifting, by a first phase angle, the first quadrature component by adding together weighted versions of the first and second quadrature components.

### BRIEF DESCRIPTION OF THE DRAWINGS

The foregoing and other purposes, features, aspects and advantages of the invention will become apparent from the following detailed description of embodiments, given by way of illustration and not limitation with reference to the accompanying drawings, in which:

FIG. 1A illustrates transmission circuitry according to an embodiment of the present invention;

FIGS. 1B and 1C are constellation diagrams each illustrating examples of phase- shift keying encoding that could be used in the embodiment of FIG. 1A;

FIG. 2A illustrates a phase shifter of the circuit of FIG. 1A in more detail in the case that the input signals are single-ended;

FIG. 2B illustrates a phase shifter of the circuit of FIG. 1A in more detail in the case that the input signals are differential;

FIG. 3 is a constellation diagram illustrating the phase of the initial input signals and the phase shifted signals of the circuitry of FIG. 1A according to an embodiment of the present invention;

FIGS. 4A and 4B illustrate differential implementations of combined phase shifting and mixing circuitry of the circuitry of FIG. 1A in more detail according to embodiments of the present invention;

FIG. 4C illustrates a variable resistance block of the phase shifting and mixing circuitry of FIGS. 4A and 4B in more detail according to an embodiment of the present invention;

FIG. 4D illustrates switching circuitry according to an embodiment of the present invention;

FIG. 5 illustrates a single-ended implementation of the combined phase shifting and mixing circuitry of FIG. 1A in more detail according to an embodiment of the present invention;

FIG. 6 illustrates reception circuitry according to an embodiment of the present invention;

FIGS. 7A and 7B illustrate differential implementations of phase shifting circuitry of the reception circuitry of FIG. 6 in more detail according to embodiments of the present invention; and

FIG. 8 illustrates a device comprising a plurality of antennas according to an embodiment of the present invention.

### DETAILED DESCRIPTION OF ILLUSTRATIVE EMBODIMENTS

Throughout the following, only features useful for the understanding of the invention will be described in detail. In particular, the systems that could comprise the phase shifter of the present invention have not been described in detail, the embodiments described herein being applicable to a wide range of systems in which quadrature signals are received and/or transmitted. These include systems employing any form of vectorial modulation. Furthermore, while in the following a phase shifter is described in the particular case of phase shifting both the I and Q components for multiple signals, it will be apparent to those skilled in the art that in certain applications such a phase shifter could be used to phase shift just one of the I and Q components of a single signal.

Furthermore, in the following, the term “quadrature components” will be used to designate a pair of wave forms, for example, sinusoids, that are out of phase by 90 degrees. For example, the “Q” component is 90 degrees behind the “I” component, although the contrary could be true. Furthermore, these quadrature components modulate at least one data signal, for example, based on an amplitude shift keying (ASK) or phase shift keying (PSK) modulation scheme.

The term “quadrature phase shift keying” (QPSK) refers to a modulation scheme that not only generates quadrature components, but in which the quadrature components represent a data signal modulated based on four phase values.

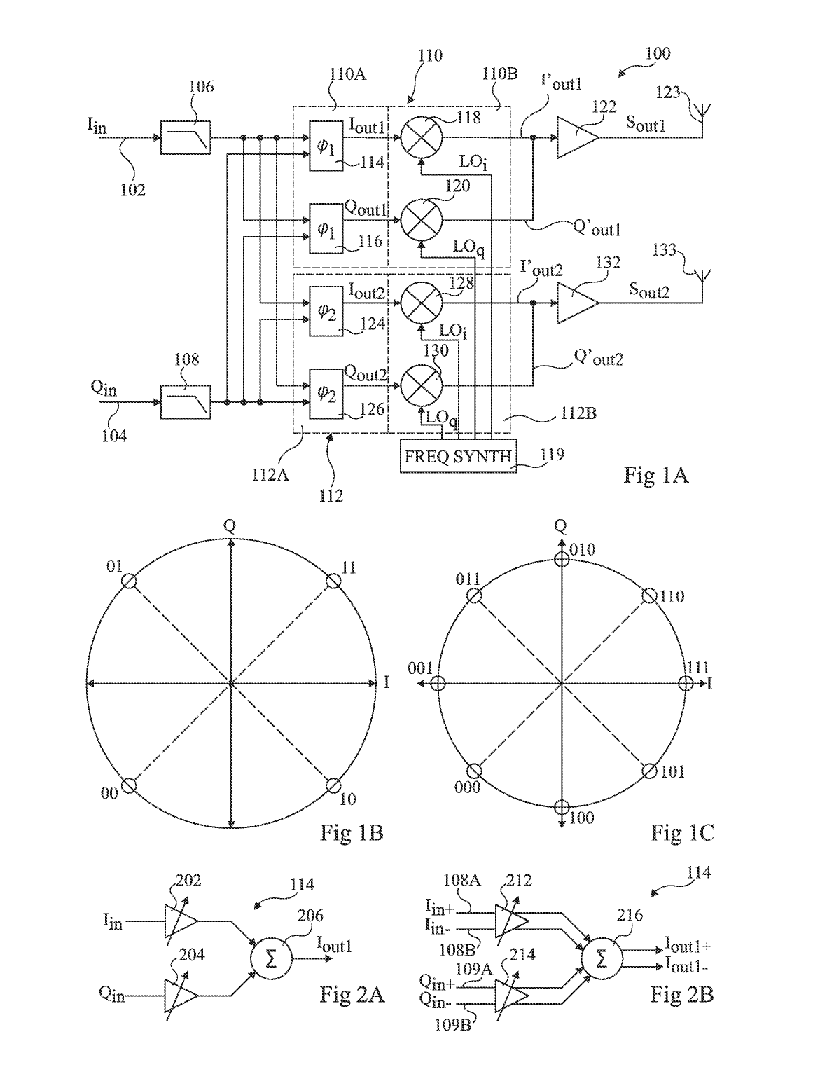

FIG. 1A illustrates transmission circuitry 100 for transmitting quadrature components, and in particular I and Q components Iᵢₙ and Qᵢₙ received on input lines 102 and 104 respectively. For example, the signals Iᵢₙ and Qᵢₙ are generated by PSK or ASK modulation circuitry (not illustrated), although in alternative examples they could be provided by other types of circuits.

The signal on each input line 102 and 104 is filtered by a respective low pass filter 106 and 108, before being supplied to each of a pair of combined phase shifting and mixing modules 110 and 112.

Module 110 comprises phase shifting circuitry 110A and mixing circuitry 110B. The phase shifting circuitry 110A comprises phase shifters 114 and 116, each of which receive both the input signals Iᵢₙ and Qᵢₙ, and each introduces a phase shift of φ₁. In particular, phase shifter 114 generates a phase-shifted signal Iₒᵤₜ₁, which corresponds to the quadrature component Iᵢₙ with a phase delay of φ₁, while phase shifter 116 generates a phase-shifted signal Qₒᵤₜ₁, which corresponds to the quadrature component Qᵢₙ with a phase delay of φ₁. The signals Iₒᵤₜ₁ and Qₒᵤₜ₁ are provided to the mixer circuitry 110B, and in particular to mixers 118 and 120 respectively. Mixers 118 and 120 multiply the signals Iₒᵤₜ₁ and Qₒᵤₜ₁ by respective carrier frequencies LOᵢ and LO_{q} provided by a frequency synthesizer 119 to generate signals I′ₒᵤₜ₁ and Q′ₒᵤₜ₁ at the output of the module 110. The signals I′ₒᵤₜ₁ and Q′ₒᵤₜ₁ are added together and provided to the input of an amplifier 122, which generates a signal Sₒᵤₜ₁ for transmission on an antenna 123 of an antenna array.

Similarly, module 112 comprises phase shifting circuitry 112A and mixing circuitry 112B. The phase shifting circuitry comprises phase shifters 124 and 126, which each receive the signals Iᵢₙ and Qᵢₙ, and each introduce a phase shift of φ₂. In particular, phase shifter 124 generates a phase-shifted signal Iₒᵤₜ₂, which corresponds to the signal Iᵢₙ with a phase delay of φ2, while phase shifter 126 generates a phase-shifted signal Qₒᵤₜ₂, which corresponds to the signal Qᵢₙ with a phase delay of φ2. The signals Iₒᵤₜ₂ and Qₒᵤₜ₂ are provided to mixers 128 and 130 respectively, which multiply these signals by the carrier frequencies LOᵢ and LO_{q} respectively to generate the signals I′ₒᵤₜ₂ and Q′ₒᵤₜ₂ at the output of module 112. The signals I′ₒᵤₜ₂ and Q′ₒᵤₜ₂ are added together and provided to the input of an amplifier 132, which generates a signal Sₒᵤₜ₂ for transmission on an antenna 133 of an antenna array. Thus Sₒᵤₜ₂ is phase-shifted with respect to Sₒᵤₜ₁ by φ2−φ1.

The antenna array for example comprises two antennas. Alternatively, the antenna array could comprise N antennas, where N is, for example, equal to between 2 to several hundred, each antenna n, for n from 1 to N, receiving via a corresponding amplifier a signal Sₙ generated by a corresponding combined phase shifting and mixing module that introduces a corresponding phase shift φₙ.

The phase shift angle φ1 introduced by the phase shifters 114, 116, phase shift angle φ2 introduced by the phase shifters 124, 126 and more generally the phase shift angle φₙ, will depend of the particular application. In one example, φ2=2_{φ1} and more generally φₙ=nφ1. However, this is but one example, and in alternative implementations there could be a non-linear progression in the phase shift for each antenna, for example, to provide second order lobe rejection.

FIG. 1B is a constellation diagram illustrating, in the Argand plane, one example of a PSK modulation scheme corresponding to QPSK (quadrature phase shift keying) for generating the quadrature components Iᵢₙ and Qᵢₙ of FIG. 1A, based on the quadrature components I and Q represented on the x-axis and y-axis respectively.

In this example, the bits “11” are encoded by in-phase versions of I and Q, the bits “10” are encoded by an in-phase version of I, and a version of Q out of phase by 180 degrees, the bits “00” are encoded by versions of both I and Q out of phase by 180 degrees, and bits “01” are encoded by a version of I out of phase by 180 degrees and an in-phase version of Q. The four constellation points encoding these four 2-bit values fall in a circle, implying that the amplitudes of the I and Q values remain constant.

FIG. 1C is a constellation diagram illustrating, in the Argand plane, a further example of a PSK modulation scheme corresponding to 8-PSK. In this example, in addition to the four constellation points of QPSK modulation, an additional four points are provided at 45°, 135°, 225° and 315° angles from the I signal, such that 3 bits of data may be encoded.

It will be apparent to these skilled in the art that the embodiments described herein could be applied to a wide range of modulation schemes, including but not limited to 4-QAM, 8-QAM, 16-QAM, 32-QAM, 64-QAM, QPSK, 8-PSK, differential PSK, and Offset PSK.

FIG. 2A illustrates the phase shifter 114 of FIG. 1A in more detail according to one example in which the quadrature components Iᵢₙ and Qᵢₙ are each single-ended. Phase shifters 116, 124 and 126, for example, have the same structure. The phase shifter 114 comprises first and second variable amplifiers 202 and 204, which apply weightings to the input signals Iᵢₙ and Qᵢₙ respectively. The outputs of the amplifiers 202 and 204 are provided to respective inputs of an adder 206, which combine these signals to provide the output signal Iₒᵤₜ₁.

FIG. 2B illustrates the phase shifter 114 of FIG. 1A in more detail according to a further example in which the quadrature components Iᵢₙ and Qᵢₙ are each differential, comprising differential components Iᵢₙ₊, Iᵢₙ₋ and Qᵢₙ₊, Qᵢₙ₋ respectively. Phase shifters 116, 124 and 126 for example have the same structure. The circuit is similar to that of FIG. 2A, except that the amplifiers 202 and 204 of FIG. 2A are replaced by differential amplifiers 212 and 214 respectively. Furthermore, the adder 206 of FIG. 2A is replaced in FIG. 2B by an adder 216, which adds the weighted Iᵢₙ₊ and Qᵢₙ₊ signals to generate the output Iₒᵤₜ₁₊ and the weighted Iᵢₙ₋ and Qᵢₙ₋ signals to generate the output signal Iₒᵤₜ₁₋.

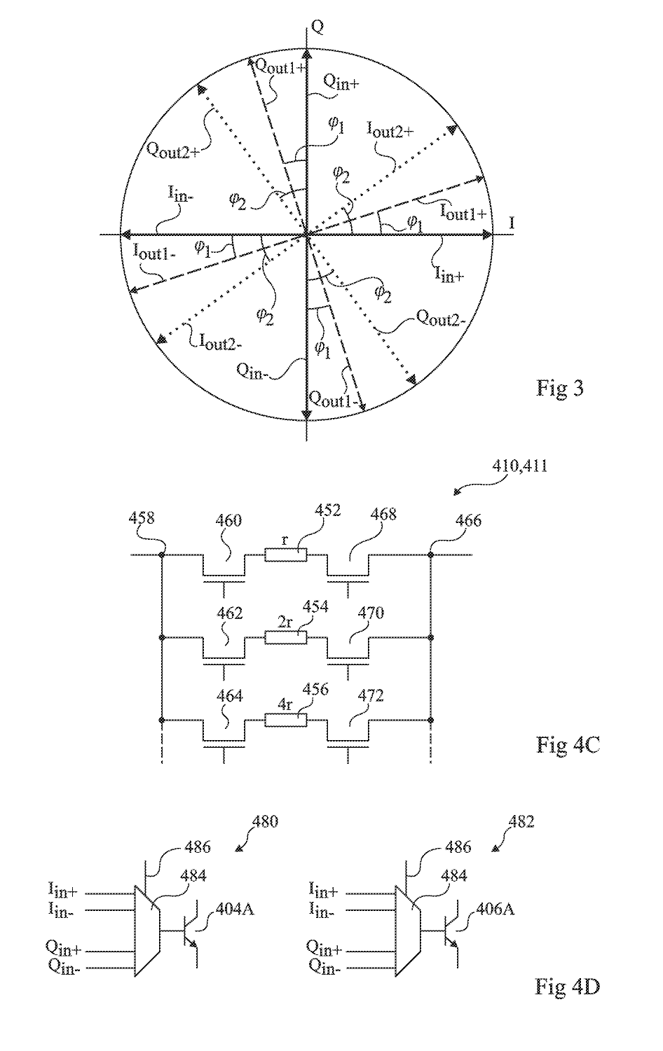

FIG. 3 is a constellation diagram illustrating, in the Argand plane, signals of the phase shifting circuitry 110A and 112A of FIG. 1A according to one example in which the quadrature components are differential, and the phase shifts φ1 and φ2 are each lower than 90°. The differential components Iᵢₙ₊ and Iᵢₙ₋ of the quadrature component Iᵢₙ are shown by arrows on the x axis, while the differential components Qᵢₙ₊ and Qᵢₙ₋ of the quadrature component Qᵢₙ are shown by arrows on the y axis. Dashed arrows represent these signals phase shifted, in other words delayed in the time domain, by an angle φ1, while dotted arrows represent these signals phase shifted, in other words delayed in the time domain, by an angle φ2. As represented by the circle touching each of these arrows, the amplitudes of the signals remain constant after the phase shift.

In alternative embodiments, the values of φ1 and φ2 could be greater than 90°, for example, anywhere up to 360°.

The phase shifters 114 and 116 phase shift each of the differential components Iᵢₙ₊, Iᵢₙ₋, Qᵢₙ₊ and Qᵢₙ₋ counter-clockwise in the Argand plane by the angle φ1, and from the diagram of FIG. 3, it will be apparent that this can be achieved by performing the following calculations:

Iₒᵤₜ₁₊=Iᵢₙ₊.cosφ1+Qᵢₙ₋.sinφ1

Iₒᵤₜ₁₋=Iᵢₙ₋.cosφ1+Qᵢₙ₊.sinφ1

Qₒᵤₜ₁₊=Qᵢₙ₊.cosφ1+Iᵢₙ₊.sinφ1

Qₒᵤₜ₁₋=Qᵢₙ₋.cosφ1+Iᵢₙ₋.sinφ1

Similarly, the phase shifters 124 and 126 phase shift each of the differential components Iᵢₙ₊, Iᵢₙ₋, Qᵢₙ₊ and Qᵢₙ₋ anti-clockwise in the Argand plane by the angle φ2, by performing the following calculations:

Iₒᵤₜ₂₊=Iᵢₙ₊.cosφ2+Qᵢₙ₋.sinφ₂

Iₒᵤₜ₂₋=Iᵢₙ₋.cosφ2+Qᵢₙ₊.sinφ2

Qₒᵤₜ₂₊=Qᵢₙ₊.cosφ2+Iᵢₙ₊.sinφ2

Qₒᵤₜ₂₋=Qᵢₙ₋.cosφ2+Iᵢₙ₋.sinφ2

Thus, in general, to apply a phase shift of φ, it can be determined that:

Iₒᵤₜ=Iᵢₙ.cosφ−Qᵢₙ.sinφ and

Qₒᵤₜ=Iᵢₙ.cosφ+Iᵢₙ.sinφ

Thus, with reference again to FIGS. 1A, 2A and 2B, the amplifier 202 or 212 of phase shifters 114 and 124, for example, applies a weighting of cosφ, while the amplifier 204 or 214 of phase shifters 114 and 124, for example, applies a weighting of −sinφ. The amplifier 202 or 212 of the phase shifters 116 and 126, for example, applies a weighting of cosφ, while the amplifier 204 or 212 of the phase shifters 116 and 126, for example, applies a weighting of sinφ.

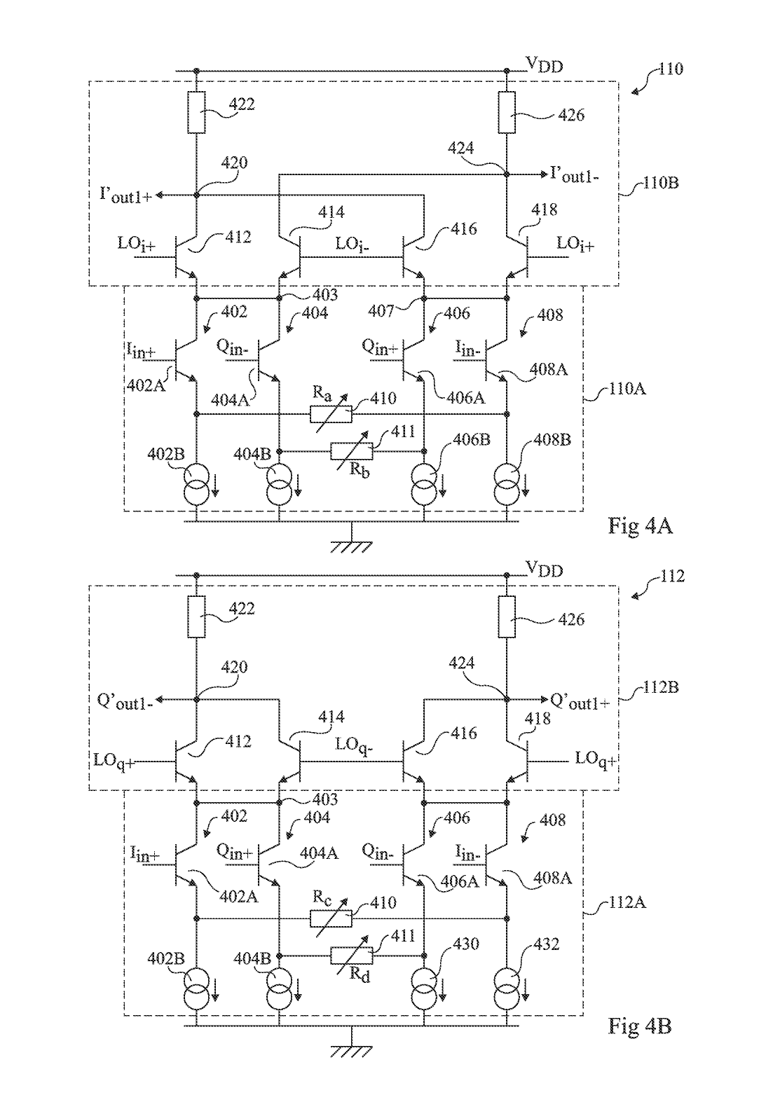

It will be apparent to those skilled in the art that the combined phase shifting and mixing modules 110 and 112 of FIG. 1A could be implemented in various ways. A differential implementation having some particular advantages will now be described with reference to FIGS. 4A to 4D.

FIGS. 4A and 4B illustrate the combined mixing and phase shifting modules 110 and 112 respectively of FIG. 1A in more detail according to one example.

The phase shifting circuitry 110A comprises a current branch 402 comprising a transistor 402A and current source 402B coupled in series between an intermediate node 403 and a ground voltage, a current branch 404 comprising a transistor 404A and current source 404B coupled in series between the intermediate node 403 and the ground voltage, a current branch 406 comprising a transistor 406A and current source 406B coupled in series between an intermediate node 407 and the ground voltage, and a current branch 408 comprising a transistor 408A and current source 408B coupled in series between the intermediate node 407 and the ground voltage.

The current sources 402B to 408B all, for example, conduct an equal current. The transistors 402A, 404A, 406A and 408A are, for example, n-type bipolar transistors receiving at their control terminals the differential components Iᵢₙ₊, Qᵢₙ₋, Qᵢₙ₊ and Iᵢₙ₋ respectively, and transistors 402A and 404A have their collectors coupled to the intermediate node 403, while transistors 406A and 408A have their collectors coupled to the intermediate node 407. The emitters of transistors 402A and 408A are coupled together via a variable resistor 410 having a resistance Rₐ, while the emitters of transistors 404A and 406A are coupled together via a variable resistor 411 having a resistance R_{b}.

The mixing circuitry 110B comprises a pair of transistors 412 and 414, in this example bipolar transistors, having their emitters coupled together to the intermediate node 403, and a pair of transistors 416 and 418, in this example also bipolar transistors, having their emitters coupled together to the intermediate node 407. Transistors 412 to 418 have their control terminals coupled to receive differential components LOᵢ₊, LOᵢ₋, LOᵢ₋ and LOᵢ₊ respectively of the carrier frequency signal LOᵢ. The collectors of transistors 412 and 416 are coupled to an output node 420, which is in turn coupled to a supply voltage V_{DD} via a resistor 422. The collectors of transistors 414 and 418 are coupled to an output node 424, which is in turn coupled to a supply voltage V_{DD} via a resistor 426. The output nodes 420 and 424 provide respectively the differential components I′ₒᵤₜ₁₊ and I′ₒᵤₜ₁₋ of the quadrature output component I′ₒᵤₜ₁.

The resistances Ra and Rb of resistors 410 and 411 have the effect of reducing the differential between the corresponding signals, and thus apply weightings to the signals Iin and Qin respectively. In one example, Ra=Rcosφ and Rb=Rsinφ, where R is a constant resistance value, for example, equal to between several tens and several thousand ohms. By providing these resistors as variable resistors, their resistance values may be tuned. Alternatively, fixed resistance resistors could be used.

As illustrated in FIG. 4B, the combined phase shifting and mixing module 112 is very similar to module 110, and like features have been labeled with like reference numerals and will not be described again in detail. The difference in the circuit of FIG. 4B is that, in the phase shifting circuitry 112A, the transistor 404A in current branch 404 receives at its control terminal the signal Qin+, while the transistor 406A in current branch 406 receives at its control terminal the signal Qin−. Furthermore, the resistor 410 has a resistance Rc, while the resistor 411 has a resistance Rd, where Rc is, for example, equal to Rsinφ, and Rd is, for example, equal to Rcosφ, where R is a constant resistance value, for example, equal to between several tens and several thousand ohms. As before, by providing these resistors as variable resistors, their resistance values may be tuned. Alternatively, fixed resistance resistors could be used.

Furthermore, in the mixing circuitry 112B the collectors of transistors 412 and 414 are coupled to node 420, while the collectors of transistors 416 and 418 are coupled to node 424. The nodes 420 and 424 respectively provide the output signals Q′out1− and Q′out+ of the output signal Q′out1. Also, the transistors 412, 414, 416 and 418 receive at their control terminals the differential components LOq+, LOq−, LOq− and LOq+ respectively of the carrier frequency signal LOq.

FIG. 4C illustrates an example implementation of the variable resistor 410 and/or 411 of FIGS. 4A and 4B in more detail. Fixed resistance resistors 452, 454 and 456 are coupled in parallel to a node 458 via respective transistors 460, 462 and 464, and to a node 466 via respective transistors 468, 470 and 472. The resistors 452 to 456, for example, have resistances of r, 2r and 4r respectively, such that by selectively activating the transistors on either side of each resistor, a combined resistance of r, 2r, 4r, 2r²/3r, 4r²/5r or 8r²/6r can be selected, where r is, for example, in the order of a few hundred Ohms. Additional resistors could be provided in parallel with resistor 452 to 456, and different resistance values would be possible, such as values r, 10r and 100r for the resistors 452 to 456 etc.

With reference again to FIG. 3, the circuit of FIGS. 4A and 4B is adapted to provide a phase shift φ of between 0 and 90°. To provide a phase shift of between 90° and 180°, it is sufficient to inverse the signals Iᵢₙ₊ and Qᵢₙ₊, and Iᵢₙ₋ and Qᵢₙ₋, at the inputs of transistors 402A, 404A, 406A and 408A. Circuitry may be provided that allows a selection to be made between a 0-90° phase shift, a 90°-180° phase shift, a 180°-270° phase shift and a 270°-360° phase shift, as will now be described with reference to FIG. 4D.

FIG. 4D illustrates switching circuits 480 and 482 that may be added at the inputs of transistors 404A and 406A respectively in FIGS. 4A and 4B. Similar circuitry may alternatively or additionally be added to the inputs of transistors 402A, 408A of FIGS. 4A and 4B.

Each circuit 480, 482 comprises a four-input multiplexer 484 receiving at its inputs the signals Iᵢₙ₊, Iᵢₙ₋, Qᵢₙ₊ and Qᵢₙ₋. A control input 486 of each multiplexer allows one of these I or Q input signals to be selected by each multiplexer, in order to switch between a phase shift of between 0 and 90°, 90° and 180°, 180° and 270° or 270° and 360°.

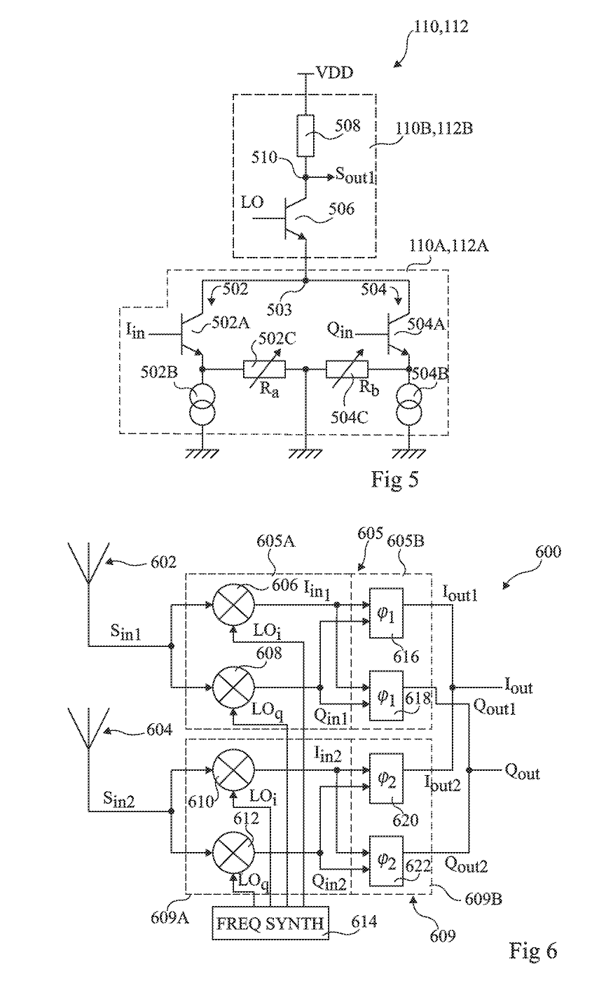

An example of a single-ended implementation of the combined mixing and phase shifting modules 110 and/or 112 will now be described with reference to FIG. 5.

FIG. 5 illustrates the phase shifting circuitry 110A/112A, which comprises a branch 502 comprising a bipolar transistor 502A and current source 502B coupled in series between an intermediate node 503 and ground, and a branch 504 comprising a bipolar transistor 504A and current source 504B coupled in series between the intermediate node 503 and ground. Furthermore, a variable resistor 502C of resistance Rₐ is coupled in parallel with the current source 502B, while a variable resistor 504C of resistance R_{b} is coupled in parallel with current source 504B. Transistor 502A receives at its control terminal the input signal Iᵢₙ, while transistor 504A receives at its control terminal the input signal Qᵢₙ. The mixing circuitry 110B comprises a bipolar transistor 506 coupled in series with a resistor 508 between the supply voltage V_{DD} and the intermediate node 503. A node 510 between transistor 506 and resistor 508 provides an output signal Sₒᵤₜ₁, corresponding to the combination of Iᵢₙ and Qᵢₙ based on the ratio between resistances Rₐ and R_{b}. Transistor 506 receives at its control terminal a carrier frequency signal LO, which could be the signal LOᵢ or LO_{q}, depending on whether the circuitry 110 or 112 is being implemented.

The variable resistors 502C and 504C perform a similar role to resistors 410 and 411 of FIGS. 4A and 4B, allowing weightings, based on the values of Rₐ and R_{b}, to be applied to the current flowing through branches 502 and 504.

The circuitry 100 of FIG. 1A corresponds to the transmission side of a communications system. The phase shifting circuitry of FIGS. 2A and 2B may equally be applied to the receive side of a communications system, as will now be described with reference to FIG. 6.

FIG. 6 illustrates receive circuitry 600 comprising a pair of antennas 602, 604, which receive signals Sᵢₙ₁ and Sᵢₙ₂ respectively. The antenna 602 is coupled to a combined phase shifting and mixing module 605, which is not exactly same as the module 110 of FIG. 1A, in that mixing is performed prior to phase shifting. Thus the signal Sᵢₙ₁ is first provided to mixing circuitry 605A of module 605, and in particular to each of a pair of mixers 606 and 608, which multiply the input signal Sᵢₙ₁ by carrier frequency signals LOᵢ and LO_{q} respectively provided by frequency synthesizer 614, to generate respective input signals Iᵢₙ₁ and Qᵢₙ₁. Similarly, the antenna 604 is coupled to a combined phase shifting and mixing module 609, and in particular to each of a pair of mixers 610 and 612 of mixing circuitry 609A, which multiply the input signal Sᵢₙ₂ by carrier frequency signals LOᵢ and LO_{q} respectively provided by the frequency synthesizer 614, to generate respective input signals Iᵢₙ₂ and Qᵢₙ₂.

Both the signals Iᵢₙ₁ and Qᵢₙ₁ are provided to each of a pair of phase shifters 616 and 618 of phase shifting circuitry 605B, while both the signals Iᵢₙ₂ and Qᵢₙ₂ are provided to each of a pair of phase shifters 620 and 622 of phase shifting circuitry 609B.

The phase shifting circuitry 605B and 609B is for example identical to that of FIG. 2A in the case of single-ended signals, or FIG. 2B in the case of differential signals.

As illustrated, the outputs Iₒᵤₜ₁ and Iₒᵤₜ₂ from the phase shifters 616 and 620 are for example added by coupling the lines together to generate an output quadrature component Iₒᵤₜ, while the outputs Qₒᵤₜ₁ and Qₒᵤₜ₂ from the phase shifters 618 and 622 are for example added by coupling the lines together to generate an output quadrature component Qₒᵤₜ.

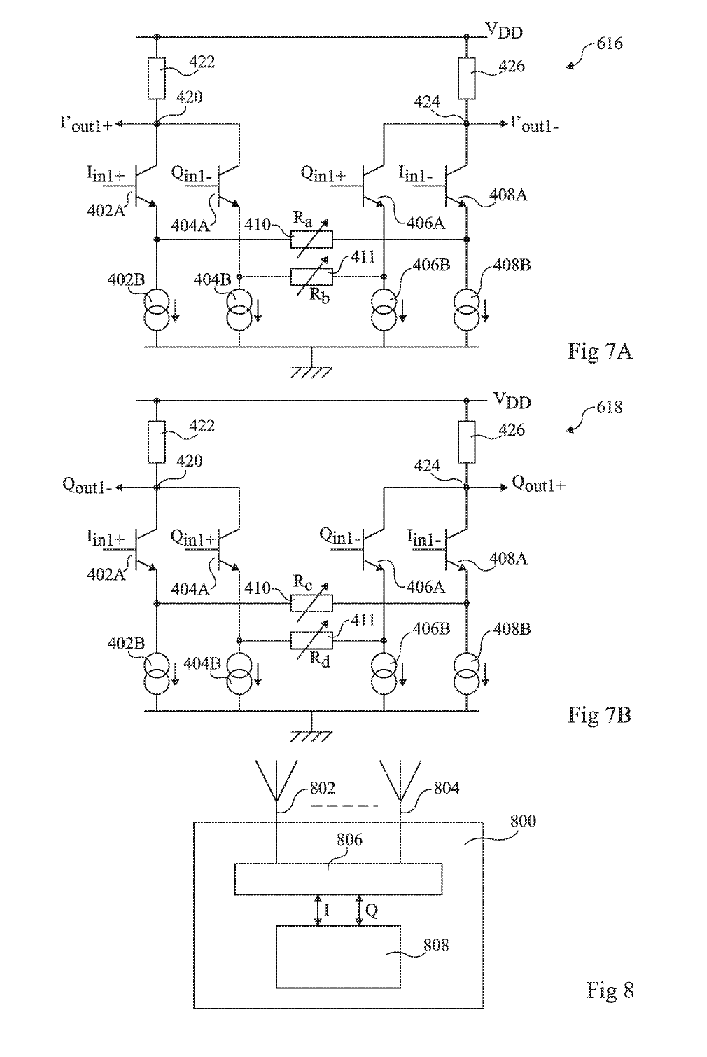

An example of the implementation of the phase shifting circuits 616 and 618 will now be described with reference to FIGS. 7A and 7B.

FIG. 7A illustrates the phase shifting circuitry 616, the implementation of which is similar to the combined mixing and phase shifting circuitry 110 of FIG. 4A, and like features have been labeled with like reference numerals. However, in the circuitry 616 of FIG. 7A, the mixing circuitry has been removed, and is for example implemented separately. In particular, transistors 412 to 418 are removed, and thus nodes 420 and 403 are merged to form a signal node 420, and nodes 424 and 407 are merged to form a signal node 424. The input signals to transistors 402A, 404A, 406A and 408A are the differential signals Iᵢₙ₁₊, Qᵢₙ₁₋, Qᵢₙ₁₊ and Iᵢₙ₁₋ respectively, supplied by the mixers 606 and 608.

FIG. 7B illustrates the phase shifting circuitry 618, the implementation of which is similar to the combined mixing and phase shifting circuitry 112 of FIG. 4B. Like features have been labeled with like reference numerals. However, in the circuitry 618 of FIG. 7B, as with the circuitry of FIG. 7A, the mixing circuitry has been removed, and is for example implemented separately. The input signals to transistors 402A, 404A, 406A and 408A are the differential signals Iᵢₙ₁₊, Qᵢₙ₁₊, Qᵢₙ₁₋ and Iᵢₙ₁₋ respectively, supplied by the mixers 606 and 608.

As with the circuits of FIGS. 4A and 4B, the circuits 480 and 482 of FIG. 4D may be used in FIGS. 7A and 7B at the control terminals of transistors 402A to 408A to select between a phase shift of between 0 and 90°, 90° and 180°, 180° and 270° or 270° and 360°.

FIG. 8 illustrates a device 800 of a communications system for transmitting and/or receiving a quadrature signal via multiple antennas 802, 804, although additional antennas may be provided. Device 800 comprises a reception/transmission block 806 coupled to the antennas, which for example comprises the transmission circuitry 100 of FIG. 1, and/or the reception circuitry 600 of FIG. 6. Furthermore, the device 800 comprises processing circuitry 808, which for example generates the quadrature components to be transmitted via the antenna, and/or processes the received quadrature signals.

The device 800 is for example a mobile telephone or base station, wireless LAN (local area network) interface, radar transmitter/receiver or other wireless transmission/reception device having multiple antennas.

An advantage of the embodiments described herein is that, by performing a phase shift of a quadrature component by adding weighted values of each quadrature component, the phase shift may be performed accurately, in particular allowing relatively precise control of the amplitudes of the signals for a broad range of frequencies. Furthermore, it is possible to accurately control the phase variation and group delay variation across the frequency bandwidth.

Furthermore, using resistors to determine the weightings leads to particularly accurate amplitude control, and by making these resistors variable, amplitude and phase imbalance correction can be provided.

The combined phasing shifting and mixing circuitry of FIGS. 4A and 4B provides the added advantages of implementing the phase shifters in the mixing circuitry in a simple fashion by the addition of very few transistors.

Having thus described at least one illustrative embodiment of the invention, various alterations, modifications and improvements will readily occur to those skilled in the art.

For example, FIGS. 4A, 4B, 5, 7A and 7B provide only example implementations, and it will be apparent to those skilled in the art that various modifications could be applied. For example, while the resistors 410 and 411 of FIGS. 4A, 4B, 7A and 7B, or resistors 502C, 504C of FIG. 5, could be implemented as fixed or variable Ohmic resistors, alternatively, fixed or variable current sources could be used.

Furthermore, it will be apparent to those skilled in the art that while the circuits of FIG. 4D allow any of the differential I or Q components to be selected for input to each transistor, alternatively, depending on the particular application of the phase shifter, the four-input multiplexers 484 could be replaced by three-input or two-input multiplexers, allowing only some of the phase groups to be selected.

Furthermore, the embodiments described herein could be applied to a wide range of PSK or ASK modulation techniques.

It will be apparent to those skilled in the art that the ground voltage described herein could be at 0 V or at any other supply voltage level V_{SS}.

1. Phase shifting circuitry for phase shifting at least one of first and second quadrature components of a data signal, the circuitry comprising:
a first phase shifter configured to phase shift, by a first phase angle, the first quadrature component by adding together weighted versions of the first and second quadrature components.

2. The phase shifting circuitry of claim 1, further comprising:
a second phase shifter configured to phase shift, by the first phase angle, the second quadrature component by adding together weighted versions of the first and second quadrature components.

3. The phase shifting circuitry of claim 2, wherein the first and second phase shifters each comprise at least one transistor for converting each of the first and second quadrature components into a current signal, and at least one resistor for adjusting each current signal to apply the weighting.

4. The phase shifting circuitry of claim 2, wherein the first phase shifter is configured to apply a weighting of cosφ to the first quadrature component and a weighting −sinφ to the second quadrature component, and the second phase shifter is configured to apply a weighting of sinφ to the first quadrature component and a weighting cosφ to the second quadrature component, where φ is the first phase angle.

5. The phase shifting circuitry of claim 4, wherein each of the first and second quadrature components is a differential signal comprising first and second differential components (Iᵢₙ₊, Iᵢₙ₋, Qᵢₙ₊, Qᵢₙ₋), and wherein the phase shifted first and second quadrature components each comprise first and second differential components (Iₒᵤₜ₊, Iₒᵤₜ₋, Qₒᵤₜ₊, Qₒᵤₜ₋) generated based on the following formulas:
Iₒᵤₜ₊=Iᵢₙ₊.cosφ+Qᵢₙ₋.sinφ
Iₒᵤₜ₋=Iᵢₙ₋.cosφ+Qᵢₙ₊.sinφ
Qₒᵤₜ₊=Qᵢₙ₊.cosφ+Iᵢₙ₊.sinφ
Qₒᵤₜ₋=Qᵢₙ₋.cosφ+Iᵢₙ₋.sinφ
where Iᵢₙ₊ and Iᵢₙ₋ are the first quadrature components, and Qᵢₙ₊and Qᵢₙ₋ are the second quadrature components, Iₒᵤₜ₊ and Iₒᵤₜ₋ are the first phase-shifted quadrature components, and Qₒᵤₜ₊ and Qₒᵤₜ₋ are the second phase-shifted quadrature components.

6. The phase shifting circuitry of claim 2, further comprising:
a third phase shifter configured to phase shift, by a second phase angle, the first quadrature component by adding together weighted versions of the first and second quadrature components; and
a fourth phase shifter configured to phase shift, by the second phase angle, the second quadrature component by adding together weighted versions of the first and second quadrature components.

7. The phase shifting circuitry of claim 2, wherein each of the first and second quadrature components is a differential signal comprising first and second differential components, and the first and second phase shifters each comprises:
first, second, third and fourth current branches respectively comprising first, second, third and fourth transistors each coupled between an intermediate node and a corresponding current source, the first and second transistors being respectively controlled by the first and second differential components of the first quadrature component, the third and fourth transistors being respectively controlled by the first and second differential components of the second quadrature component;
a first resistor coupled between the first and second branches; and
a second resistor coupled between the third and fourth branches, wherein resistance values of the first and second resistors determine the weighting values applied to first and second quadrature components respectively.

8. The phase shifting circuitry of claim 7, wherein the first and second resistors comprise variable resistors controllable by a control signal.

9. The phase shifting circuitry of claim 7, wherein the first and second resistors of the first phase shifter have resistances of Rcosφ and Rsinφ respectively, and the first and second resistors of the second phase shifter have resistances of Rsinφ and Rcosφ respectively, where R is a constant and φ is the first phase angle.

10. The phase shifting circuitry of claim 1, wherein the first and second quadrature components represent data modulated based on phase shift keying (PSK) or amplitude shift keying (ASK).

11. The phase shifting circuitry of claim 1, wherein the first and second quadrature components represent data modulated based on quadrature phase shift keying (QPSK).

12. RF transmission circuitry comprising:
phase shifting circuitry comprising a first phase shifter configured to phase shift, by a first phase angle, a first quadrature component of a data signal by adding together weighted versions of the first quadrature component and a second quadrature component of the data signal;
a first mixer configured to multiply the phase shifted first quadrature component by a first carrier frequency signal;
a second mixer configured to multiply the phase shifted second quadrature component by a second carrier frequency signal, wherein an output of the first mixer and output of the second mixer are summed to provide a first phase shifted signal; and
an antenna node coupled to transmit the first phase shifted signal.

13. The RF transmission circuitry of claim 12, wherein the phase shifting circuitry further comprises a second phase shifter configured to phase shift, by the first phase angle, the second quadrature component by adding together weighted versions of the first and second quadrature components.

14. The RF transmission circuitry of claim 13, wherein each of the first and second quadrature components is a differential signal comprising first and second differential components, and the first and second phase shifters each comprises:
first, second, third and fourth current branches respectively comprising first, second, third and fourth transistors each coupled between an intermediate node and a corresponding current source, the first and second transistors being respectively controlled by the first and second differential components of the first quadrature component, the third and fourth transistors being respectively controlled by the first and second differential components of the second quadrature component;
a first resistor coupled between the first and second branches; and
a second resistor coupled between the third and fourth branches, wherein resistance values of the first and second resistors determine the weighting values applied to first and second quadrature components respectively.

15. The RF transmission circuitry of claim 14, wherein the first mixer is coupled between a supply voltage and the first, second, third and fourth current branches of the first phase shifter, and the second mixer is coupled between the supply voltage and the first, second, third and fourth current branches of the second phase shifter.

16. The RF transmission circuitry of claim 12, further comprising an antenna coupled to the antenna node to transmit the first phase shifted signal.

17. RF reception circuitry comprising:
an antenna node adapted to receive a first input signal;
a first mixer configured to multiply the first input signal by a first carrier frequency signal to generate a first quadrature component;
a second mixer adapted to multiply the second input signal by a second carrier frequency signal (LO_{q}) to generate a second quadrature component; and
phase shifting circuitry comprising a first phase shifter configured to phase shift, by a first phase angle, the first quadrature component by adding together weighted versions of the first quadrature component and a second quadrature component of the data signal.

18. The RF reception circuitry of claim 17, wherein the phase shifting circuitry further comprises a second phase shifter configured to phase shift, by the first phase angle, the second quadrature component by adding together weighted versions of the first and second quadrature components.

19. The RF reception circuitry of claim 18, wherein each of the first and second quadrature components is a differential signal comprising first and second differential components, and the first and second phase shifters each comprises:
first, second, third and fourth current branches respectively comprising first, second, third and fourth transistors each coupled between an intermediate node and a corresponding current source, the first and second transistors being respectively controlled by the first and second differential components of the first quadrature component, the third and fourth transistors being respectively controlled by the first and second differential components of the second quadrature component;
a first resistor coupled between the first and second branches; and
a second resistor coupled between the third and fourth branches, wherein resistance values of the first and second resistors determine the weighting values applied to first and second quadrature components respectively.

20. The RF reception circuitry of claim 17, further comprising an antenna coupled to the antenna node.

21. A method of phase shifting at least one of first and second quadrature components of a data signal, the method comprising:
phase shifting, by a first phase angle, the first quadrature component by adding together weighted versions of the first and second quadrature components.
